(19) United States
(12) Patent Application Publication
(10) Pub. No.: US 2014/0362624 A1
(43) Pub. Date: Dec. 11, 2014

(54) SPIN TORQUE DIODE ELEMENT, RECTIFIER AND POWER GENERATION MODULE

(71) Applicant: Masaki Yamada, Tokyo (JP)

(72) Inventor: Masaki Yamada, Tokyo (JP)

(73) Assignee: Hitachi, Ltd., Tokyo (JP)

(21) Appl. No.: 14/372,572

(22) PCT Filed: Jan. 17, 2012
(86) PCT No.: PCT/JP2012/050771

§ 371 Date: Jul. 16, 2014

(51) Int. Cl. H01L 29/82; H01L 29/861; H02M 7/06; H01L 43/02

(52) U.S. Cl. CPC H01L 29/82; H01L 43/02; H01L 29/861; H02M 7/06
USPC 363/126; 257/421

(57) ABSTRACT

Provided is a spin torque diode element having an excellent frequency characteristic and an excellent rectification efficiency. The spin torque diode element according to the present invention includes first and second magnetization free layers and a magnetization fixed layer that is shared by the magnetization free layers and has a configuration that a current can be flown to the first and second magnetization free layers via the magnetization fixed layer.

### TECHNICAL FIELD

The present invention relates to a spin torque diode element.

### BACKGROUND ART

In recent advanced information society, there has been developed various devices that use a radio in a GHz band. Among them, attention has been focused on a rectification effect using a spin torque diode effect.

The spin torque diode effect is a rectification effect using a TMR (Tunneling Magnetic Resistance) element and uses resistance differences generated between a parallel condition or an antiparallel condition of magnetizations of two magnetic bodies. A rectifier using this effect is excellent in view of heat resistance, compared to a rectifier of a conventional semiconductor. Further, since the magnetic resonant frequency of magnetic bodies is used as the rectification effect, this provides an excellent frequency characteristic, and an application to a high-frequency filter or a high-frequency power generation module in a GHz band area is expected.

In following NPL 1, the spin torque diode effect is described in detail. In PTL 1, as an example of a signal detection device using a magnetoresistance effect element, a configuration having a differential amplifier that amplifies and outputs a direct voltage generated at both ends of plural magnetoresistance effect elements 2a, 2b is developed.

### CITATION LIST

### Patent Literature

PTL 1: Japanese Patent Application Laid-Open No. 2009-59986

### Non Patent Literature

NPL 1: A. A. Tulapurkar et al, “Spin-Torque Diode Effect in Magnetic Tunnel Junctions,” Nature 438 (2005), 339

### SUMMARY OF INVENTION

### Technical Problem

Next, the spin torque diode effect will be explained in detail. According to NPL 1, when an alternating current Iac=I*sin(2πft) having the frequency f flows to a TMR element, a magnetization of a free layer changes its direction due to torque caused by the current. Here, when the magnetization that changes according to the spin transfer torque is set as S(θ), the following Equation 1 can be expressed. “A” and “B” are constant numbers and can be determined according to the aeolotropy of the spin transfer torque.

S(θ)=cos θ+A*sin(2πft)+B*cos(2πft) Equation 1

On the other hand, a resistance R caused by changes of relative angles of the magnetization can be expressed as following Equation 2 with a resistance change rate ΔR (=Rap−Rp). “Rap” and “Rp” are resistance of cases that the two magnetizations are antiparallel and parallel, respectively.

R=Rp+½*ΔR*(1−S) Equation 2

In this case, voltages V generated at the both ends of the TMR elements are expressed in following Equation 3.

$$\begin{matrix}V = R * Iac \\ = - A / 4 * Δ R * I + C * Δ R * I * sin ( 2 π ft ) + \\ D * Δ R * I * sin ( 4 π ft - δ )\end{matrix} \qquad Equation 3$$

Constant numbers C, D, and 6 are expressed as following Equations 4 to 7 respectively.

C=((Rap+Rp)/(Rap−Rp))−cos θ)/2 Equation 4

D=SQRT(A*A+B*B) Equation 5

sin δ=A/SQRT(A*A+B*B) Equation 6

cos δ=B/SQRT(A*A+B*B) Equation 7

Since the first member in Equation 3 is a member that does not depend on the time, it means that, when an alternating current is applied to the TMR element, A/4*ΔR*I which is the DC half-wave rectification is generated as negative rectification. The second member is a member that depends on a positive applied AC half-wave rectification I*sin(2πft), and the third member is a member being proportional to a negative double harmonic component I*sin(4πft).

As described above, since the voltages at the both ends of the TMR element are positive and negative and combined signals of different frequencies, the frequency characteristic becomes complicated and a disordered voltage waveform is seen. Thus, when the spin torque diode effect is simply applied to a high-frequency filter, it is assumed that the frequency characteristic is deteriorated.

Further, regarding Equation 3, since the harmonic component of the double frequency in the third member is dominant, a half-wave rectification of the double frequency is seen in practical in view of the rectification effect based on time average and the rectification efficiency is not supposedly desirable.

According to the above consideration, when the spin torque diode element is used in a high-frequency filter or rectifier, there is a problem in view of the frequency characteristic and rectification efficiency.

The present invention has been made to solve the problem described above and provides a spin torque diode element having an excellent frequency characteristic and an excellent rectification efficiency.

### Solution to Problem

The spin torque diode element according to the present invention includes first and second magnetization free layers and a magnetization fixed layer that is shared by the magnetization free layers and has a configuration that a current can be flown to the first and second magnetization free layers via the magnetization fixed layer.

### Advantageous Effects of Invention

In the spin torque diode element according to the present invention, since the directions of currents flowing in the first and second magnetization free layers via the magnetization fixed layer become opposite to each other, the directions of spin torque working in each magnetization free layer become opposite to each other. Thus, the second member in Equation 3 can be canceled out each other. With this configuration, the voltage characteristic of the entire element is only a harmonic component of the double frequency and this provides an excellent frequency characteristic. Further, also in view of the rectification effect, since the doubly periodic full-wave rectification is available, a high rectification efficiency can be expected.

### BRIEF DESCRIPTION OF DRAWINGS

FIG. 1 is a schematic view of a conventional spin torque diode element.

FIG. 2 is a view illustrating calculation results of time dependence of voltages at both ends of the conventional spin torque diode element and respective elements.

FIG. 3 is a schematic view of a spin torque diode element 100.

FIG. 4 is a view illustrating calculation results of a time change pattern of alternating current outputs from an AC source 1 and time dependence of a composite output voltage V0 corresponding to the time change pattern.

FIG. 5 is a schematic view of a rectifier 200 according to a second embodiment.

FIG. 6 is a view illustrating calculation results of time dependence of an output voltage V0′ of the rectifier 200 according to the second embodiment.

FIG. 7 is a view illustrating direct voltage waveforms output from the rectifier 200 when magnetic resonant frequencies of first magnetization free layers 3-1 and 3-2 are made to be f0.

FIG. 8 is a schematic view of a rectifier 300 according to a third embodiment.

FIG. 9 is a schematic view of an adder circuit 310.

FIG. 10 is a view illustrating calculation results of time dependence of a direct voltage output from the rectifier 300.

FIG. 11 is a schematic view of a power generation module 400 according to a fourth embodiment.

FIG. 12 is a view explaining a process of manufacturing the power generation module 400.

### DESCRIPTION OF EMBODIMENTS

In the purpose of comparison, a configuration of a spin torque diode element according to the present invention will be explained after explaining a conventional spin torque diode element.

### <Conventional Spin Torque Diode Element>

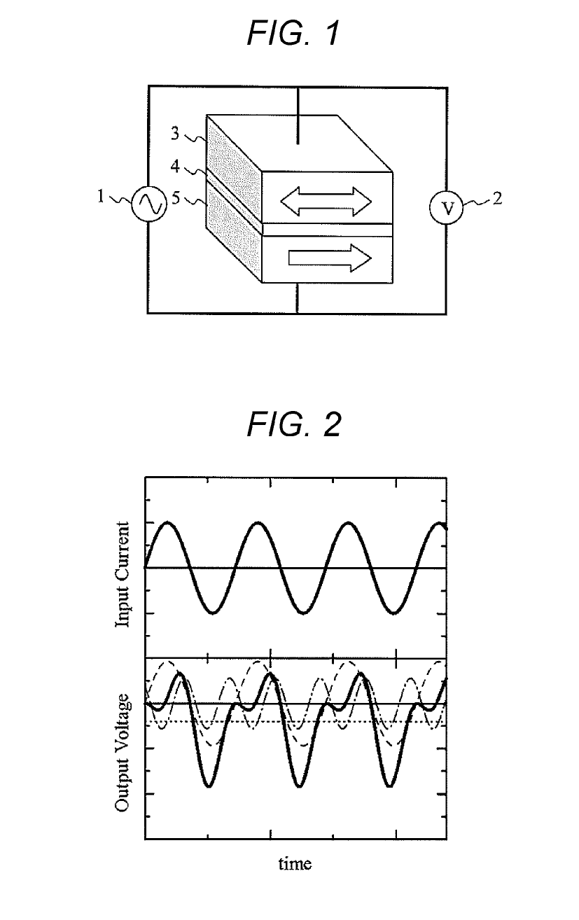

FIG. 1 is a schematic view of a conventional spin torque diode element. The basic configuration is a spin valve element, which is called TMR element, having a configuration of three layers of a magnetization free layer 3, a tunnel barrier layer 4 and a magnetization fixed layer 5. For the magnetization free layer 3 and magnetization fixed layer 5, a general magnetic body including Co, Fe and Ni is used. Magnetism of the magnetization fixed layer 5 is fixed in one direction with an antiferromagnetic body such as MnPt and MnIr, for example. For the tunnel barrier layer 4, an insulator thin film such as an oxidation product such as ZnO and MgO is used.

To the TMR element, an AC source 1 and a voltage detector 2 are connected. The AC source 1 passes an alternating current to the magnetization free layer 3, the tunnel barrier layer 4, and the magnetization fixed layer 5. The voltage detector 2 detects voltages generated at both ends of the magnetization free layer 3 and magnetization fixed layer 5.

When a current is applied downward from above in FIG. 1 (The direction of an electron transfer is upward from bottom and this current direction is assumed to be a positive direction.), spin-polarized electrons passing though the magnetization fixed layer 5 is spin-polarized in a magnetization direction of the magnetization fixed layer 5. The spin-polarized electrons apply spin transfer torque, which is parallel to the magnetization direction of the magnetization fixed layer 5, to the magnetization of the magnetization free layer 3. Thus, the magnetization direction of the magnetization fixed layer 5 and the magnetization direction of the magnetization free layer 3 become parallel to each other. It is known that a TMR element causes low electric resistance when the magnetization direction of a magnetization fixed layer and the magnetization direction of a magnetization free layer are parallel to each other. As a result, a low positive voltage is generated at both ends of the TMR element.

On the other hand, when a current is applied in a negative direction (The electron transfer is downward from above.), only spin-polarized electrons which are polarized parallel to the magnetization direction of the magnetization fixed layer 5 go though to the magnetization fixed layer 5. In the magnetization free layer 3, spin-polarized electrons reflected by an interface apply spin torque anti-parallel to the magnetization direction of the magnetization fixed layer 5 and the magnetization directions of the magnetization fixed layer 5 and magnetization free layer 3 are respectively stabilized in an anti-parallel condition. Thus, when a current is applied in the negative direction, a negative high voltage is generated at the both ends of the TMR element.

In other words, when an alternating current is applied to the TMR element, a low positive voltage and a high negative voltage are generated and the spin torque diode elements provides an effect that generally rectifies alternating power to negative voltage in view of time average.

FIG. 2 is a view illustrating calculation results of time dependence of voltages at both ends of the conventional spin torque diode element and respective components thereof. Here, the calculation was made using the above Equation 3. The first member of Equation 3 that is a member not having time dependence (DC half-wave rectification) is represented with a dotted line, the second member that is a member having dependence of applied AC half-wave rectification I*sin (2πft) (current half-wave rectification) is represented with a dashed line, and the third member that is a negative member proportional to a double harmonic half-wave rectification I*sin (4πft) (harmonic component) is represented with a dashed-dotted line. Further, a composite voltage which is a summation of the above is represented with a continuous line. The respective parameters are Rp=100Ω, ΔR=300Ω, and A=B.

As expressed by Equation 3 and Equation 4, when a resistance change rate ΔR/Rp becomes larger, the applied AC half-wave rectification in the second member becomes larger and frequency characteristic is extremely deteriorated. In other words, regarding the spin torque diode effect, when the output is made higher by increasing the resistance change rate ΔR/Rp, the frequency characteristic may be also deteriorated. Thus, the rectification effect of the conventional spin torque diode element generally becomes half-wave rectification with double frequency as illustrated in FIG. 2, and only the DC half-wave rectification (the first member of Equation 3) can be used according to time average. In view of the above, the present invention provides a configuration that can reduce the component of the second member of Equation 3.

### First Embodiment

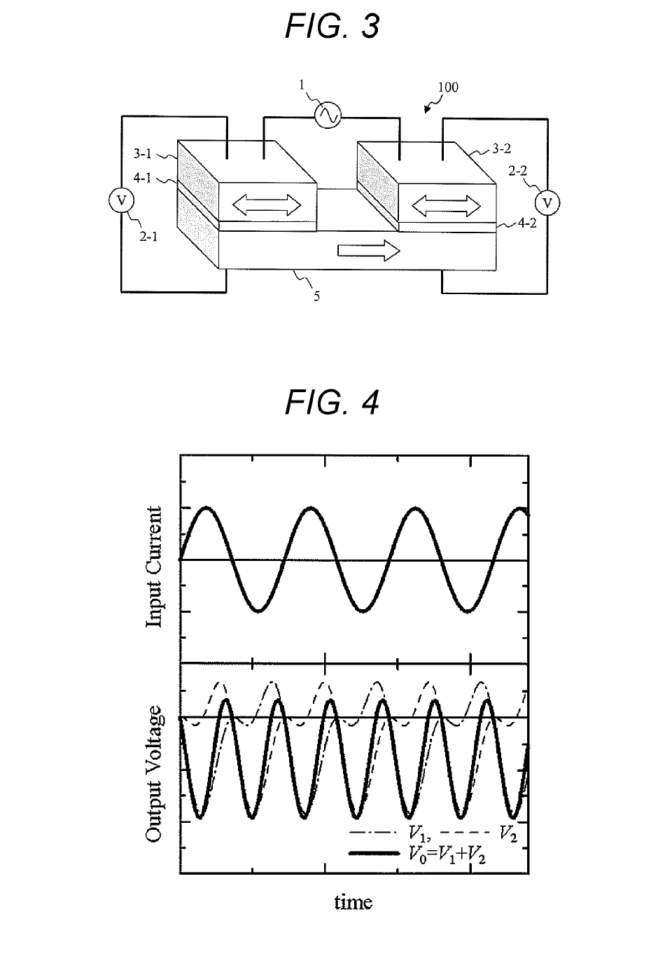

FIG. 3 is a schematic view of a spin torque diode element 100 according to the present invention. The spin torque diode element 100 includes a pair of magnetization free layers 3-1 and 3-2 which share a magnetization fixed layer 5. The first magnetization free layer 3-1 is electrically connected with the magnetization fixed layer 5 via a first tunnel barrier layer 4-1 and the second magnetization free layer 3-2 is electrically connected with the magnetization fixed layer 5 via the second tunnel barrier layer 4-2. In FIG. 3, the tunnel barrier layers are separately formed; however, the first and second tunnel barrier layers may be formed to be shared.

The first magnetization free layer 3-1 and the second magnetization free layer 3-2 are general magnetic conductive materials including Co, Fe, Ni and the like. Ideally, it is preferable that magnetic resonant frequencies of magnetizations of the first and second magnetization free layers are equivalent; however, this does not impose any limitation. It is preferable that the tunnel barrier layers 4-1 and 4-2 are made of MgO, ZnO or the like which are a barrier layer materials having a high spin injection efficiency; however, this does not impose any limitation and a general barrier layer material may be used and this does not make any change in the effect. As a material of the magnetization fixed layer 5, a versatile magnetic conductive material including Co, Fe, Ni and the like may be used. The magnetization of the magnetization fixed layer 5 is fixed in one direction by an antiferromagnetism such as MnIr and Pt. The magnetization fixing method of the magnetization fixed layer 5 is not limited to this method.

An AC source 1 applies a current from the first magnetization free layer 3-1 to the second magnetization free layer 3-2 or in the opposite direction. Since the first magnetization free layer 3-1 and the second magnetization free layer 3-2 are electrically connected via the magnetization fixed layer 5, an alternating current flows between the first magnetization free layer 3-1 and the second magnetization free layer 3-2 via the magnetization fixed layer 5. The first magnetization free layer 3-1 and the second magnetization free layer 3-2 are connected by a preferable electric wire.

A voltage detector 2-1 detects a potential difference V1 between the first magnetization free layer 3-1 and the magnetization fixed layer 5 and a voltage detector 2-2 detects a potential difference V2 between the second magnetization free layer 3-2 and the magnetization fixed layer 5. A first voltage wire to lead the potential difference V1 and a second voltage wire to lead the potential difference V2 are provided according to need.

The following explains voltages V1 and V2 in a case that positive current flows in the direction from the first magnetization free layer 3-1 to the second magnetization free layer 3-2 (The electrons transfer in the direction from 3-2 to 5 and from 5 to 3-1). In the first magnetization free layer 3-1, since spin-polarized electrons parallel to the magnetization direction of the magnetization fixed layer 5 pass through, the magnetization direction of the first magnetization free layer 3-1 which receives the spin torque becomes parallel to the magnetization direction of the magnetization fixed layer 5. Thus, the voltage detector 2-1 detects a potential difference V1 which is positive and low. On the other hand, in the second magnetization free layer 3-2, since the spin-polarized electrons spinning antiparallel to the magnetization direction of the magnetization fixed layer 5 are reflected, the magnetization direction of the second magnetization free layer 3-2 which receives spin torque becomes antiparallel to the magnetization direction of the magnetization fixed layer 5. Thus, the voltage detector 2-1 detects a potential difference V2 which is negative and high. When the composite voltage of the V1 and V2 is set as V0 and a positive current flows to the spin torque diode element 100, “V0=V1+V2” becomes a negative potential difference.

When a negative current is applied to the spin torque diode element 100, a reduction opposite to the above description occurs, so that the magnetizations of the first magnetization free layer 3-1 and magnetization fixed layer 5 become antiparallel and the magnetizations of the second magnetization free layer 3-2 and magnetization fixed layer 5 become parallel. Thus, the voltage detector 2-1 detects a high negative voltage and the voltage detector 2-2 detects a low positive voltage. The composite voltage V0 becomes a negative potential difference.

In other words, the spin torque diode element 100 according to the present invention outputs a negative composite voltage V0 regardless of the current polarity.

FIG. 4 is a diagram illustrating a pattern of changes with time course of an alternating current output by the AC source 1 and calculation results of time dependence of the composite output voltage V0 corresponding to the pattern. The voltages V1 and V2 detected by the voltage detectors 2-1 and 2-2 are represented with a dashed-dotted line and a dashed line respectively.

As discussed above, the change with time course in the voltage V1 detected by the voltage detector 2-1 is given by following Equation 3-1.

V1=−A/4*ΔR*I+C*ΔR*I*sin(2πft)+D*ΔR*I*sin(4 πft−δ) Equation 3-1

On the other hand, since the voltage V2 detected by the voltage detector 2-2 always indicates a potential difference opposite to the voltage V1, its phage changes with time course as being shifted from the phase of V1 by π. Thus, the change of the voltage V2 with time course is given by following Equation 3-2.

V2−A/4*ΔR*I+C*ΔR*I*sin(2π(ft+½))+D*ΔR I*sin(4π((ft+½))−δ)=−A/4*ΔR*I−C*ΔR*I*sin(2πft)+D*ΔR*I*sin(4πft−δ) Equation 3-2

Thus, the composite voltage V0 is expressed as following Equation 8.

$$\begin{matrix}V 0 = V 1 + V 2 \\ = - A / 4 * Δ R * I + D * Δ R * I * sin ( 4 π ft - δ )\end{matrix} \qquad Equation 8$$

In other words, regarding the composite voltage V0 of the spin torque diode element 100 according to the present invention, since the second members in Equation 3-1 and Equation 3-2 (applied AC half-wave rectification) are canceled out, the time dependence member of V0 is only the harmonic component with double frequency of the second member in Equation 8. With this configuration, since more than one frequency characteristics do not exist, this provides an excellent frequency characteristic. Further, as illustrated in FIG. 4, comparing to the conventional spin torque diode element, a doubly periodic full-wave rectification becomes available and a high rectification efficiency can be realized.

### First Embodiment

### Conclusion

As described above, the spin torque diode element 100 according to the first embodiment includes a first magnetization free layer 3-1 and a second magnetization free layer 3-2 which share a magnetization fixed layer 5 in common and has a configuration that a current flows between the first magnetization free layer 3-1 and second magnetization free layer 3-2 via the magnetization fixed layer 5. With this configuration, the applied AC half-wave rectification of the composite voltage V0 is canceled out and the frequency characteristic and the rectification efficiency can be improved.

Further, with the spin torque diode element 100 according to the first embodiment, the integration as an entire device becomes easier by providing the magnetization fixed layer 5 to be shared by the magnetization free layers. With this configuration, a higher output can be achieved by arranging the elements in an array or in a three-dimensional integration.

Here, for example, when PTL 1 is used to achieve the same effect as the spin torque diode element 100 according to the first embodiment, the circuit configuration may be more complicated since a circuit configuration for applying an alternating current is separately required to make directions of the current flowing in each element become opposite after the magnetization directions of the magnetization fixed layers are made corresponding between the elements. The first embodiment is assumed to be advantageous that the effect can be produced in each element by properly designing the structure of the spin torque diode element 100 itself.

### Second Embodiment

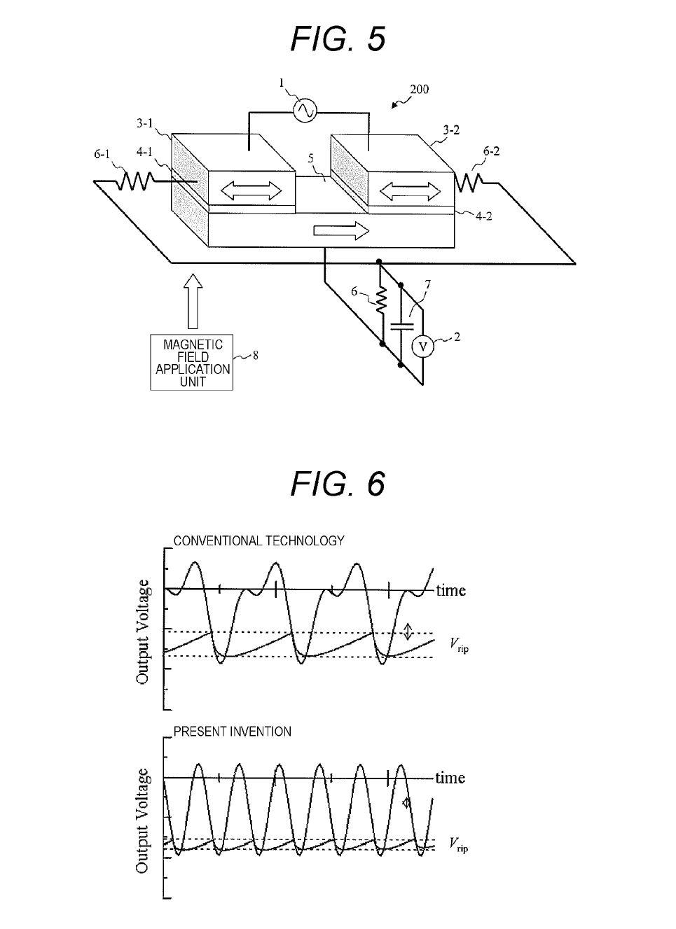

FIG. 5 is a schematic view of a rectifier 200 according to a second embodiment of the present invention. The rectifier 200 according to the second embodiment includes a parallel circuit in which a resistor 6, a capacitor 7 and a voltage detector 2 are connected in parallel, a first converting resistor 6-1, a second converting resistor 6-2, and a magnetic field application unit 8, in addition to the spin torque diode element 100 explained in the first embodiment. An “adder circuit” in the second embodiment is relevant to a part of the parallel circuit which obtains a composite voltage.

To add the voltage V1 and voltage V2, a first voltage wire and a second voltage wire need to be connected. However, when those wires are simply connected, the potentials of those voltage wires become the same. Accordingly, by inserting the first converting resistor 6-1 and the second converting resistor 6-2, the voltages V1 and V2 are once converted into current values and the currents are serially added so that the voltages V1 and V2 are added equivalently. As a matter of convenience of the adding process, it is preferable that resistance values or the first converting resistor 6-1 and second converting resistor 6-2 are equal; however, this does not impose any limitation. The current that flows to the first converting resistor 6-1 is represented with I1 and the current that flows to the second converting resistor 6-2 is represented with I2.

The resistor 6 is a sensing resistor for sensing the current values which are serially added via the first converting resistor 6-1 and second converting resistor 6-2 as a voltage value once again. The voltage detector 2 detects voltage at the both ends of the resistor 6, that is the composite voltage V0. The capacitor 7 is for smoothing the composite voltage V0.

The magnetic field application unit 8 applies an external magnetic field on a film surface of the magnetization free layer. The resonant frequency of the magnetization of each magnetization free layer can be changed by changing the strength of the external magnetic field or the application direction. The magnetic resonant frequency effect will be described later.

The configuration of the rectifier 200 has been explained. Next, operation of the rectifier 200 will be explained with calculating formulas.

The voltage generated between the first magnetization free layer 3-1 and the magnetization fixed layer 5 is V1 and, when the current I1 flows to the first converting resistor 6-1 (The resistivity is assumed as Rs.) and the resistor 6 (The resistivity is assumed as R0.), a voltage drop occurs. Further, when the current I2 flows from the second magnetization free layer 3-2 to the magnetization fixed layer 5, a voltage drop also occurs. These voltage drops are expressed in following Equation 9 and Equation 10.

V1−Rs*I1−R0*I1=0 Equation 9

V2−Rs*I2−R0*I2=0 Equation 10

In this case, the voltage V0′ which is observed with the voltmeter 2 is obtained as following Equation 11 based on Equation 9 and Equation 10.

V0′=(1/(1+(Rs/R0)))*(V1+V2) Equation 11

The voltage V0′ has dependence of sin(4πft) on the time but stable direct voltage can be obtained by smoothing with the capacitor 7.

FIG. 6 is a diagram illustrating calculation results of the time dependence of output voltage V0′ of the rectifier 200 according to the present second embodiment. In the purpose of comparison, calculation results of time dependence of output voltage with a conventional spin torque diode element are also illustrated.

When they are compared, the sizes of the ripple voltages Vrip associated with the smoothing by the capacitor differ. In the conventional spin torque diode element, since there is a member proportional to an alternating current component indicating the time dependence of sin(2πft), a waveform peak interval becomes larger due to the half-wave rectification effect and, accordingly, the ripple voltage Vrip also becomes larger. On the other hand, in the spin torque diode element according to the present invention, since only the harmonic component of sin(4πft) produces the full-wave rectification effect, the waveform peak interval becomes smaller and, accordingly, the ripple voltage Vrip also becomes smaller. Since the ripple voltage Vrip can be reduced up to 50%, a stable direct voltage can be obtained.

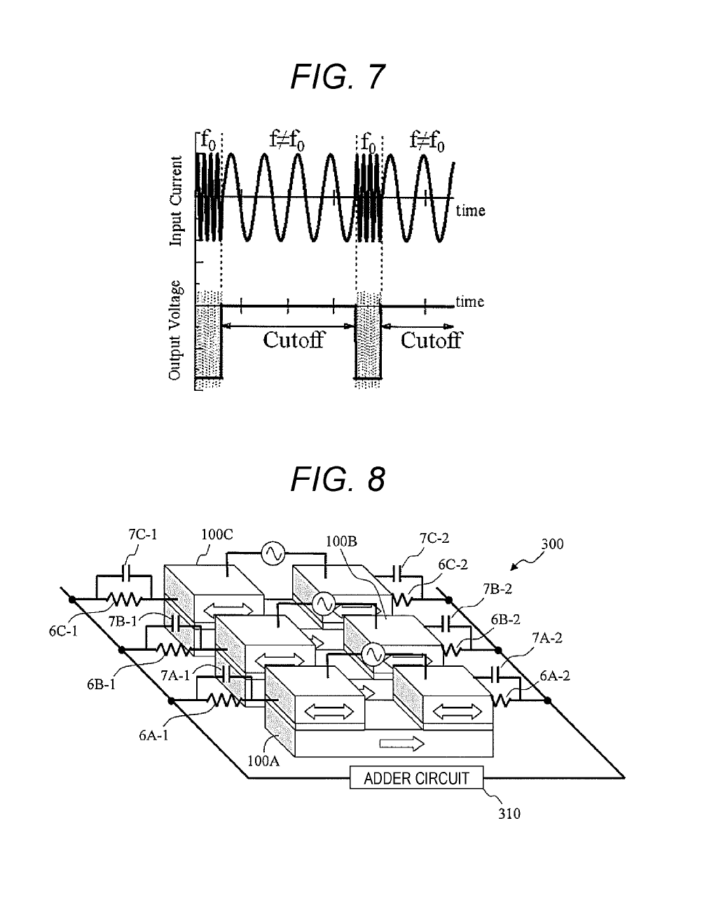

FIG. 7 is a view illustrating direct voltage waveforms output by the rectifier 200 when the magnetic resonant frequencies of the respective first magnetization free layers 3-1 and 3-2 are made to be f0. In a case that the AC source 1 applies alternating currents of various frequencies to the spin torque diode element 100, the largest direct voltage is generated when the frequency of the alternating current corresponds to the magnetic resonant frequency f0, and the rectification effect when the frequency of the alternating current does not correspond to f0 becomes much smaller. In other words, when the frequency of the alternating current is not f0, output voltage V0 hardly changes and the rectifier 200 functions as a high-pass filter with characteristic frequency f=f0.

Further, since the magnetic resonant frequency of the magnetic body can be changed by the external magnetic field output from the magnetic field application unit 8, the characteristic frequency of the rectifier 200 can be controlled by changing the strength and direction of the external magnetic field output from the magnetic field application unit 8.

### Second Embodiment

### Conclusion

As described above, the rectifier 200 according to the second embodiment can produce a preferable rectification effect using the spin torque diode element 100 according to the first embodiment.

Further, the rectifier 200 according to the second embodiment can operate as a high-pass filter that produces a greatest rectification effect by making the frequency of the alternating current applied by the AC source 1 to be corresponding to the magnetic resonant frequency f0 and blocks outputs in other cases. Further, the characteristic frequency can be controlled by changing the magnetic resonant frequency f0 using the external magnetic field output from the magnetic field application unit 8.

### Third Embodiment

FIG. 8 is a schematic view of a rectifier 300 according to the third embodiment of the present invention. The rectifier 300 has a configuration in which three spin torque diode elements 100 (100A, 100B, 100C) explained in the first embodiment are connected in parallel and further includes an adder circuit 310.

Although reference numerals are not indicated in FIG. 8 for convenience of description, in the spin torque diode element 100A, first and second magnetization free layers are 3A-1 and 3A-2 respectively, first and tunnel barrier layers are 4A-1 and 4A-2 respectively, and a magnetization fixed layer is 5A; in the spin torque diode element 100B, first and second magnetization free layers are 3B-1 and 3B-2 respectively, first and tunnel barrier layers are 4B-1 and 4B-2 respectively, and a magnetization fixed layer is 5B; and in the spin torque diode element 100C, first and second magnetization free layers are 3C-1 and 3C-2 respectively, first and tunnel barrier layers are 4C-1 and 4C-2 respectively, and a magnetization fixed layer is 5C. AC sources connected to the spin torque diode elements are 1A, AB, and 1C respectively. It is preferable that these AC sources are shared in common; however, this does not impose any limitation.

The magnetic resonant frequency of the first and second magnetization free layers 3A-1 and 3A-2 is indicated by f1, the magnetic resonant frequency of the first and second magnetization free layers 3B-1 and 3B-2 is indicated by f2, and the magnetic resonant frequency of the first and second magnetization free layers 3C-1 and 3C-2 is indicated by f3.

In the respective spin torque diode elements, a first parallel circuit is connected to the first magnetization free layer, and a second parallel circuit is connected to the second magnetization free layers. The first parallel circuit connected to the first magnetization free layer 3A-1 has a configuration that the first converting resistor 6A-1 and the capacitor 7A-1 are connected in parallel, and the second parallel circuit connected to the second magnetization free layer 3A-2 has a configuration that the second converting resistor 6A-2 and the capacitor 7A-2 are connected in parallel. The first parallel circuit connected to the first magnetization free layer 3B-1 has a configuration that the first converting resistor 6B-1 and the capacitor 7B-1 are connected in parallel, and the second parallel circuit connected to the second magnetization free layer 3B-2 has a configuration that the second converting resistor 6B-2 and the capacitor 7B-2 are connected in parallel. The first parallel circuit connected to the first magnetization free layer 3C-1 has a configuration that the first converting resistor 6C-1 and the capacitor 7C-1 are connected in parallel, and the second parallel circuit connected to the second magnetization free layer 3C-2 has a configuration that the second converting resistor 6C-2 and the capacitor 7C-2 are connected in parallel. The functions of these parallel circuits are the same as that of the parallel circuit in the second embodiment, which was explained with reference to FIG. 5.

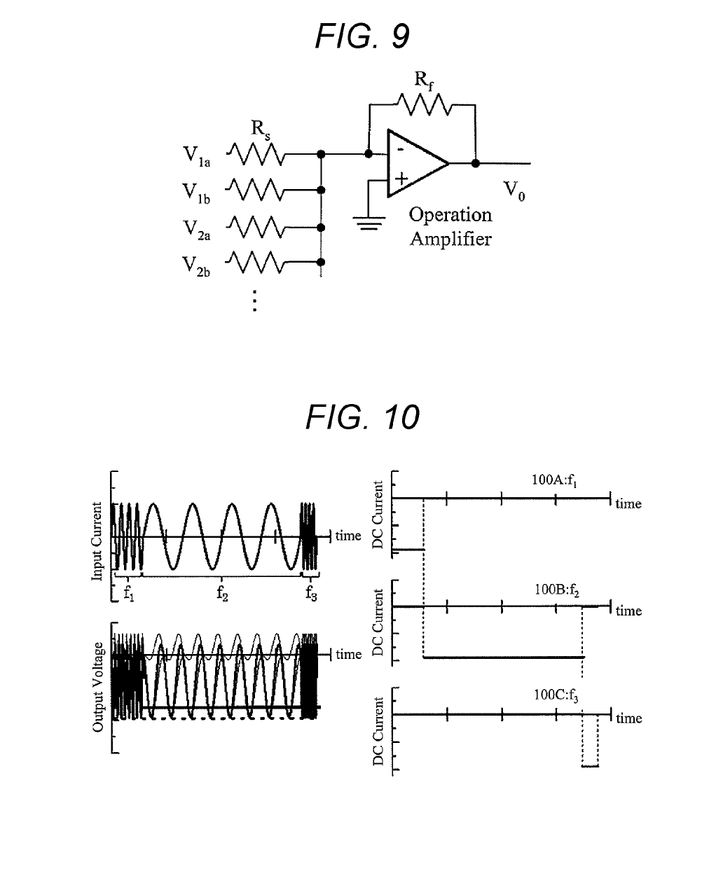

FIG. 9 is a schematic diagram of the adder circuit 310. The voltage at the both ends of each spin torque diode element 100 is serially added as a current value by the first converting resistor 6-1 or the second converting resistor 6-2. The adder circuit 310 amplifies the serially added current value with an operational amplifier and obtains composite voltage V0.

It is assumed that voltage V1a is generated between the first magnetization free layer 3A-1 and the magnetization fixed layer 5A, and voltage V2a is generated between the second magnetization free layer 3A-2 and the magnetization fixed layer 5A. The resistance value of each first converting resistor 6A-1 and second converting resistor 6A-2 is assumed as Rs. In this case, the current that flows to each converting resistor are V1a/Rs, V2a/Rs respectively. These current flows are added in the adder circuit 310 and resultant current (V1a+V2a)/Rs flows to an amplified resistance Rf of the operational amplifier. Thus, it is expressed as:

composite voltage V0=(V1a+V2a)*Rf/Rs

In other words, an amplification factor in the adder circuit 310 is determined based on a ratio of resistance Rf and converting resistor Rs in the adder circuit 310. The spin torque diode elements 100B and 100C have the same configuration.

FIG. 10 is a view illustrating calculation results of time dependence of direct voltage output from the rectifier 300. Here, it is assumed that the alternating currents output from the AC sources 1A to 1C have frequencies f1, f2, and f3.

The spin torque diode elements 100A to 100C produce the greatest rectification effect when alternating currents corresponding to the respective magnetic resonant frequencies are applied. Here, composite voltages V0′A to V0′C output from the spin torque diode element 100A to 100C can be expressed as:

V0′A=(V1a+V2a)*Rf/Rs,V0′B=(V1b+V2b)*Rf/Rs, and

V0′C=(V1c+V2c)*Rf/Rs.

When the resistance value Rp and resistance change rate ΔR/Rp of each spin torque diode element are equal, it is expressed as:

V1a=V2a=V1b= . . . =V1c=V2c.

In other words, the values of direct voltages which are smoothed by the capacitor also become all equal. That is, the rectifier 300 according to the third embodiment outputs constant direct voltage using frequency bands f1 to f3. Since the magnetic resonant frequency band can be made wider by controlling the size, shape, composition or the like of the magnetic body material of the magnetization free layer, it is assumed that the rectifying characteristic of the rectifier 300 can be made to have a wider bandwidth.

### Third Embodiment

### Conclusion

As described above, the rectifier 300 according to the third embodiment has a configuration in which a plurality of pin torque diode elements 100 having different magnetic resonant frequencies are connected in parallel and further includes the adder circuit 310 that adds voltages at both ends of the each elements. This provides a wider bandwidth of rectifying characteristics compared with a rectifier using a single spin torque diode element 100.

### Fourth Embodiment

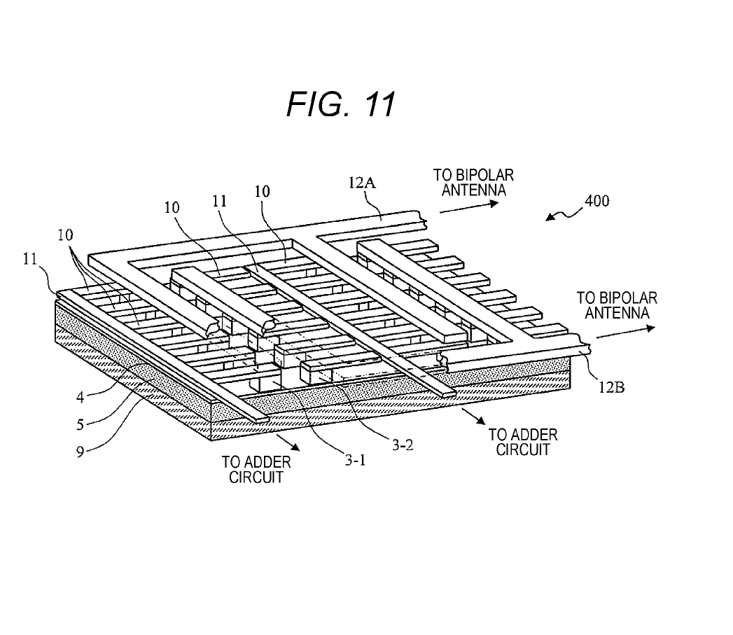

FIG. 11 is a schematic view illustrating a power generation module 400 according to a fourth embodiment of the present invention. The power generation module 400 has a configuration that an antiferromagnetic layer 9, a magnetization fixed layer 5, and a tunnel barrier layer 4 are laminated on a substrate, and a pair of pillar-shaped magnetization free layers 3-1 and 3-2 are formed on the tunnel barrier layer 4. Although the pair of magnetization free layers 3-1 and 3-2 that face to each other have a same magnetic resonant frequency, the respective pair of magnetization free layer pillar have magnetic resonant frequencies different from one another. As a method for controlling the magnetic resonant frequency, for example, film thickness of the magnetization free layers may be made different in each pair of pillars.

To each of the magnetization free layers, the parallel circuit 10 having the converting resistor and capacitor connected in parallel is electrically connected. The current generated in the parallel circuit 10 is collected in the adder circuit (not illustrated) via the conducting wire 11. The waveguides 12A and 12B supply alternating currents received by a bipolar antenna, which is not illustrated, to the pairs of the magnetization free layers.

The above configuration is the same as the configuration of the rectifier 300 explained in the third embodiment. Here, the bipolar antenna is provided as a substitute for the AC source 1 and the harmonic electromagnetic wave received by the bipolar antenna is converted into alternating current and supplied to the spin torque diode elements 100. The spin torque diode elements 100 rectify the input alternating current and output direct voltage. In other words, the spin torque diode elements 100 can operate as a power generation module that takes harmonic electromagnetic waves as input and outputs direct voltage.

### Fourth Embodiment

### Conclusion

As described above, according to the fourth embodiment, a power generation module 400 having a rectification effect for outputting a direct voltage when a harmonic electromagnetic wave is input can be provided. The power generation module 400 can provide higher power with its in-plane integration and, further, remarkably increase the power generation amount by arranging the power generation module 400 in a manner of a three dimension.

Further, in the fourth embodiment, the waveguide 12 is formed to supply alternating currents to a pair of the magnetization free layer pillars at the same time. Since the magnetic resonant frequency of the pair of the magnetization free layer pillars are different from each other, the rectification effect can be provided in a wide frequency bandwidth, similarly to the third embodiment. In other words, a wideband power generation module 400 can be provided.

### Fifth Embodiment

In the fifty embodiment of the present invention, a manufacturing method of the power generation module 400 explained in the fourth embodiment will be explained.

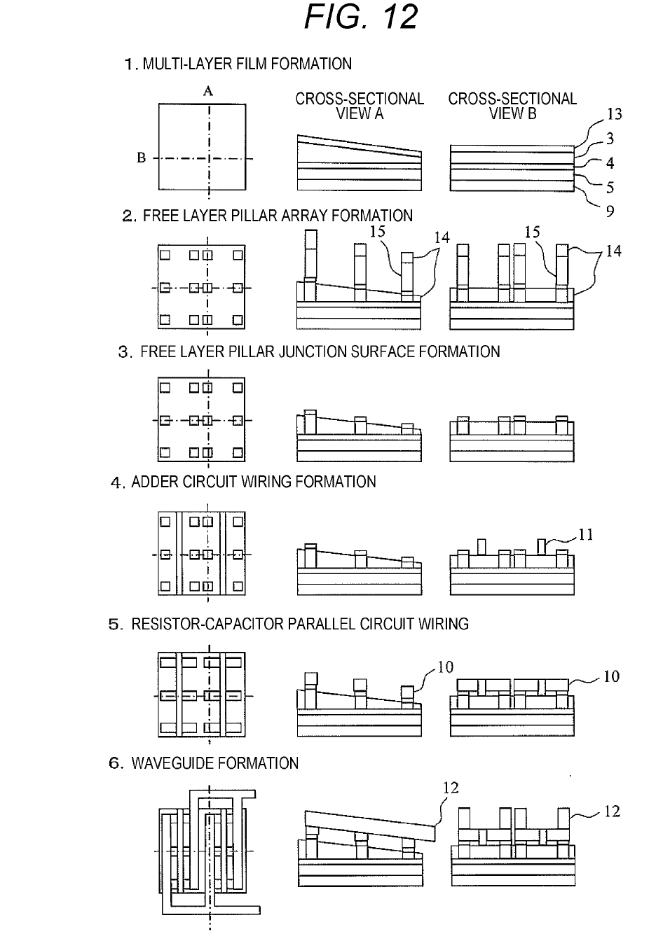

FIG. 12 is a view explaining a process to manufacture the power generation module 400. The views in the left column in FIG. 12 are relevant to top views of the power generation module 400 and the views in the middle and right columns are sectional views. Hereinafter, each process in FIG. 12 will be explained.

### (FIG. 12: Process 1: Multi-Layer Film Formation)

On a silicon wafer, a 5-nm Pt layer was formed and then an antiferromagnetic layer 9: MnIr (20 nm), a magnetization fixed layer 5: CoFeB (5 nm) Ru (0.8 nm) CoFeB (3 nm), a tunnel barrier layer 4: MgO (1.0 nm), a magnetization free layer (ferromagnetic body) 3: CoFeB(t), a cap layer 13: Ta (5 nm) Ru (5 nm) Ir (5 nm) were formed in order. For the layers, an RF magnetron sputtering system was used and CoFeB of the magnetization free layer 3 was made having a layer thickness of from 3 to 10 nm in the A cross-sectional direction by sputtering in an oblique direction to form a film.

### (FIG. 12: Process 2: Free Layer Pillar Array Creation)

A pillar array of the magnetization free layer 3 was formed by producing a square resist pattern 15 of 100×100 nm2 by using an EB exposure apparatus. The interval between a pair of the magnetization free layer pillars was made 1 μm, and the interval between the pairs of the magnetization free layer pillars is made 200 μm. In total, 10,000 pairs of magnetization free layer pillars were formed by a lithography method within an area of 30×30 mm2. These resist patterns 15 are used as a mask and the array of the pairs of magnetization free layer pillars are processed by a milling method. As an amount of processing, it was pruned up to the right above the tunnel barrier layer 4. After processing by the milling process, 25 nm alumina was formed as a protective film 14.

### (FIG. 12: Process 3: Free Layer Pillar Junction Surface Formation)

To remove the alumina protective film 14 and resist 15 on the magnetization free layer pillar which were created in Process 2, a magnetization free layer pillar junction surface was formed by using a liftoff method. The liftoff method is executed with a removing solution and polishing and the alumina protective film 14 and the resist 15 are removed.

### (FIG. 12: Process 4: Adder Circuit Wiring Formation)

A conducting wire 11 for the adder circuit wiring was created by a liftoff method. This time, a 2-μm wiring pattern was created by using a positive resist and Cu (50 nm) was formed on the entire surface. After that Cu wiring was created by using the removing solution.

### (FIG. 12: Process 5: Resistor-Capacitor Parallel Circuit Wiring)

The parallel circuit having the converting resistor 6 and capacitor 7 connected in parallel and the magnetization free layer pillars created in Process 3 are wired respectively by wire bonding. Further, current generating in each spin torque diode element 100 is connected to a part of the Cu wiring produced in Process 4. The resistance value of the converting resistor 6 and the electric capacitance of the capacitor 7 used in this case were 100Ω and 10,000 μF respectively.

### (FIG. 12: Process 6: Waveguide Formation)

To supply alternating current to the pairs of the magnetization free layer pillars, a coplanar waveguide 12 with which easier in-plane wring is available. In final, the power generation module 400 is completed by connecting the waveguide 12 with the bipolar antenna, and the adder circuit with the Cu wiring respectively. The inner resistance of the adder circuit is made Rf=1 MΩ.

### Sixth Embodiment

In a sixth embodiment of the present invention, the output voltage of the power generation module 400 created in the fifth embodiment will be explained.

The characteristic of the spin torque diode element 100 constituting the power generation module 400 were found as Rp=50 KΩ, ΔR/Rp=300%, and magnetic resonant frequency from 3 to 10 GHz. When alternating current having the amplitude 1 μA and the frequency 5 GHz was applied, the voltage generated at the both ends of the spin torque diode element 100 was Vpp=−30 mV. Further, in the magnetization free layer pillar array, since pillars having the magnetic resonant frequency of 5 GHz were about 10%, of the entire pillars, the voltage generated via the adder circuit was 300 V. As a result, the direct voltage of 300 V is generated when alternating current having the amplitude 10 mA and the frequency 5 GHz are applied to the power generation module 400.

### REFERENCE SIGNS LIST

1: AC source
2: voltage detector
3: magnetization free layer
4: tunnel barrier layer
5: magnetization fixed layer
6: converting resistor
7: capacitor
8: magnetic field application unit
9: antiferromagnetic layer
10: parallel circuit
11: conducting wire
12: waveguide
13: cap layer
14: protective film
15: resist
100: spin torque diode element
200: rectifier
300: rectifier
400: power generation module

1. A spin torque diode element, comprising:
first and second magnetization free layers;
a magnetization fixed layer shared by the first and second magnetization free layers;
a first tunnel barrier layer provided between the first magnetization free layer and the magnetization fixed layer;
a second tunnel barrier layer provided between the second magnetization free layer and the magnetization fixed layer;
an electric wire configured to lead a current which flow the first magnetization free layer and the second magnetization free layer via the magnetization fixed layer;
a first voltage wire configured to output a first voltage between the first magnetization free layer and the magnetization fixed layer; and
a second voltage wire configured to output a second voltage between the second magnetization free layer and the magnetization fixed layer.

2. A rectifier, comprising:
the spin torque diode element according to claim 1; and
an adder circuit configured to add the first voltage and the second voltage.

3. The rectifier according to claim 2, wherein
the first voltage wire and the second voltage wire are connected in parallel; and
the adder circuit comprises
a first resistor configured to induce a first current using the first voltage;
a second resistor configured to induce a second current using the second voltage; and
an adder configured to obtain a sum of the first voltage and the second voltage by converting, into a voltage value, the current which is obtained by serially adding the first current and the second current.

4. The rectifier according to claim 2, further comprising a capacitor configured to be connected to the adder circuit in parallel and smooth the voltage which the first voltage and the second voltage are combined.

5. The rectifier according to claim 2, wherein the magnetic resonant frequency of the first magnetization free layer and the magnetic resonant frequency of the second magnetization free layer are substantially equal.

6. The rectifier according to claim 2, further comprising a magnetic field application unit configured to vary magnetic resonant frequencies of the first and second magnetization free layers by applying an external magnetic field to the first and second magnetization free layers.

7. The rectifier according to claim 3, further comprising a plurality of the spin torque diode elements,
wherein the magnetic resonant frequencies of the spin torque diode elements are made to be different from each other, and
the adder circuit adds the first voltage and the second voltage output from each spin torque diode element.

8. The rectifier according to claim 7, wherein
a pair of the first voltage wire and the second voltage wire in the each spin torque diode element is connected to each other in parallel, and
the adder circuit
comprises the first resistor and the second resistor of the each spin torque diode element and
obtains a sum of the first voltage and the second voltage by converting, into a voltage value, a current obtained by serially adding the first current and the second current for the each spin torque diode element.

9. A power generation module, comprising:
the rectifier according to claim 7; and
a waveguide configured to supply an alternating current to the pair of the first magnetization free layer and the second magnetization free layer of the each spin torque diode element,
wherein the waveguide supplies the alternating current to the pair of the first magnetization free layer and the second magnetization free layer in the each spin torque diode element at the same time.
